(19) United States
(12) Patent Application Publication
(10) Pub. No.: US 2017/0207774 A1
(43) Pub. Date: Jul. 20, 2017

(54) D LATCH CIRCUIT

(71) Applicant: TEXAS INSTRUMENTS INCORPORATED, Dallas, TX (US)

(72) Inventors: Diptendu Ghosh, Kolkata (IN); Petteri Matti Litmanen, Richardson, TX (US); Siraj Akhtar, Richardson, TX (US)

(21) Appl. No.: 15/408,412

(22) Filed: Jan. 17, 2017

Related U.S. Application Data
(60) Provisional application No. 62/279,199, filed on Jan. 15, 2016.

(51) Int. Cl. H03K 5/00; H03K 3/356

(52) U.S. Cl. CPC H03K 5/00006; H03K 3/356104

(57) ABSTRACT

A latch circuit includes first and second inverters, each with latching (inner) and clocking (outer) PMOS/NMOS transistor pairs in a series/stack configuration. A first inverter includes a D_latching PMOS/NMOS transistor pair, drain-connected at a D node. A first /clock PMOS transistor is coupled between a high rail and a source terminal of the D_latching PMOS transistor, and a first clock NMOS transistor is coupled between a low rail and the source terminal of the D_latching NMOS transistor. A second inverter includes a Dbar_latching PMOS/NMOS transistor pair, drain-connected at a Dbar node. A second /clock PMOS transistor is coupled between the high rail and the source terminal of the Dbar_latching PMOS transistor, and a second clock NMOS transistor is coupled between the low rail and the Dbar_latching NMOS transistor. A cross-coupling switch circuit connected between the D node and the Dbar node. The first and second /clock PMOS transistors can be combined as a single /clock PMOS transistor connected between the high rail and the source terminals of respectively the D_latching and Dbar_latching PMOS transistors, and the first and second clock NMOS transistors can be combined as a single clock NMOS transistor connected between the low rail and the source terminals of respectively the D_latching and Dbar_latching NMOS transistors. As an example application, the latch circuit can be used in a quadrature (IQ) frequency divider.

### CROSS-REFERENCE TO RELATED APPLICATIONS

Priority is claimed under 37 CFR 1.78 and 35 USC 119(e) to U.S. Provisional Application 62/279,199 (Docket TI-76395PS), filed 15 Jan. 2016, which is incorporated by reference.

### BACKGROUND

Technical Field

This Patent Disclosure relates generally to frequency dividers, such as a quadrature frequency divider for use in direct-conversion wireless transceiver applications.

Related Art

Frequency dividers use clocked latches in a master slave configuration.

The speed of the divider, i.e., the maximum frequency up to which the divider will operate, is limited by the speed of the latches.

While this Background information references a PCB/Chassis system, the Disclosure in this Patent Document is more generally directed to ground fault detection based on capacitive sensing.

### BRIEF SUMMARY

This Brief Summary is provided as a general introduction to the Disclosure provided by the Detailed Description and Drawings, summarizing aspects and features of the Disclosure. It is not a complete overview of the Disclosure, and should not be interpreted as identifying key elements or features of, or otherwise characterizing or delimiting the scope of, the disclosed invention.

The Disclosure describes apparatus and methods for a D latch circuit, such as can be used in a frequency divider.

According to aspects of the Disclosure, a latch circuit includes first and second inverters, each with latching (inner) and clocking (outer) PMOS/NMOS transistor pairs in a series/stack configuration. A first inverter includes a D_latching PMOS/NMOS transistor pair, drain-connected at a D node. A first /clock PMOS transistor is coupled between a high rail and a source terminal of the D_latching PMOS transistor, and a first clock NMOS transistor is coupled between a low rail and the source terminal of the D_latching NMOS transistor. A second inverter includes a Dbar_latching PMOS/NMOS transistor pair, drain-connected at a Dbar node. A second /clock PMOS transistor is coupled between the high rail and the source terminal of the Dbar_latching PMOS transistor, and a second clock NMOS transistor is coupled between the low rail and the Dbar_latching NMOS transistor. A cross-coupling switch circuit connected between the D node and the Dbar node. The first and second /clock PMOS transistors can be combined as a single /clock PMOS transistor connected between the high rail and the source terminals of respectively the D_latching and Dbar_latching PMOS transistors, and the first and second clock NMOS transistors can be combined as a single clock NMOS transistor connected between the low rail and the source terminals of respectively the D_latching and Dbar_latching NMOS transistors. As an example application, the latch circuit can be used in a quadrature (IQ) frequency divider.

Other aspects and features of the invention claimed in this Patent Document will be apparent to those skilled in the art from the following Disclosure.

### BRIEF DESCRIPTION OF THE DRAWINGS

FIG. 1 illustrates a conventional latch, configured with two switched differential inverters, with an inner series switch that is controlled by an incoming clock signal (φ and φ_{bar} or clock and /clock), with cross-coupling PMOS/NMOS.

FIG. 2 illustrates an example embodiment of a latch design according to this Disclosure.

FIG. 3 illustrates an example embodiment of a frequency divider including two D latches according to this Disclosure, such as the example embodiment illustrated in FIG. 2.

FIG. 4 illustrates an example direct conversion TX/RX transceiver design, including TX/RX and FBRX signal paths with respective PLLs, each implemented with a frequency divider such as illustrated in FIG. 3 using D latches according to this Disclosure, based on the example embodiment illustrated in FIG. 2.

### DETAILED DESCRIPTION

This Description and the Drawings constitute a Disclosure for a D latch circuit, including describing example embodiments, and illustrating various technical features and advantages.

In brief overview, a latch circuit includes first and second inverters, each with latching (inner) and clocking (outer) PMOS/NMOS transistor pairs in a series/stack configuration. A first inverter includes a D_latching PMOS/NMOS transistor pair, drain-connected at a D node. A first /clock PMOS transistor is coupled between a high rail and a source terminal of the D_latching PMOS transistor, and a first clock NMOS transistor is coupled between a low rail and the source terminal of the D_latching NMOS transistor. A second inverter includes a Dbar_latching PMOS/NMOS transistor pair, drain-connected at a Dbar node. A second /clock PMOS transistor is coupled between the high rail and the source terminal of the Dbar_latching PMOS transistor, and a second clock NMOS transistor is coupled between the low rail and the Dbar_latching NMOS transistor. A cross-coupling switch circuit connected between the D node and the Dbar node. The first and second /clock PMOS transistors can be combined as a single /clock PMOS transistor connected between the high rail and the source terminals of respectively the D_latching and Dbar_latching PMOS transistors, and the first and second clock NMOS transistors can be combined as a single clock NMOS transistor connected between the low rail and the source terminals of respectively the D_latching and Dbar_latching NMOS transistors. As an example application, the latch circuit can be used in a quadrature (IQ) frequency divider.

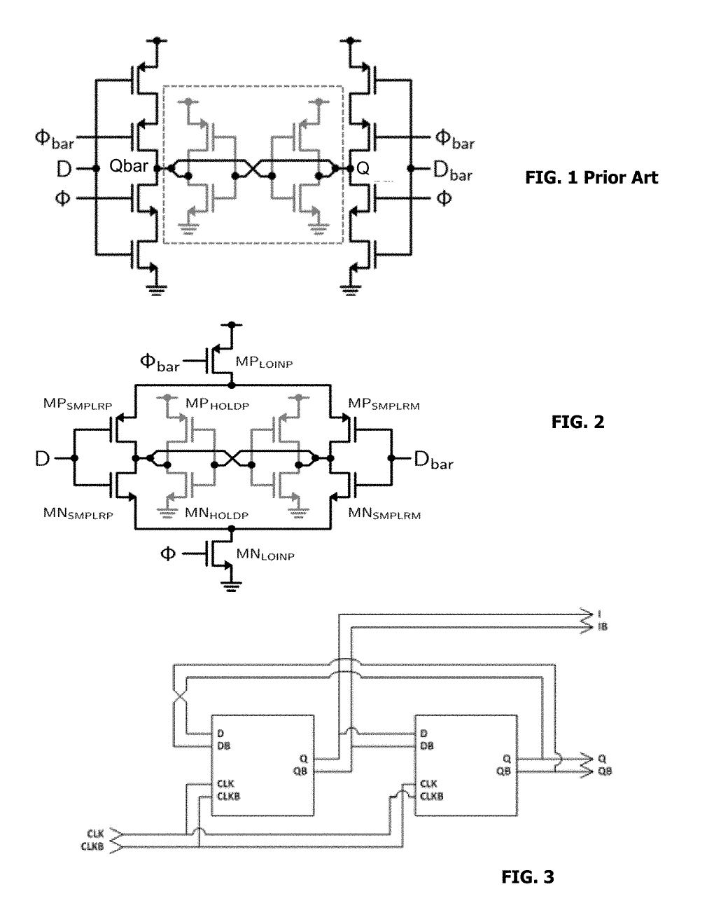

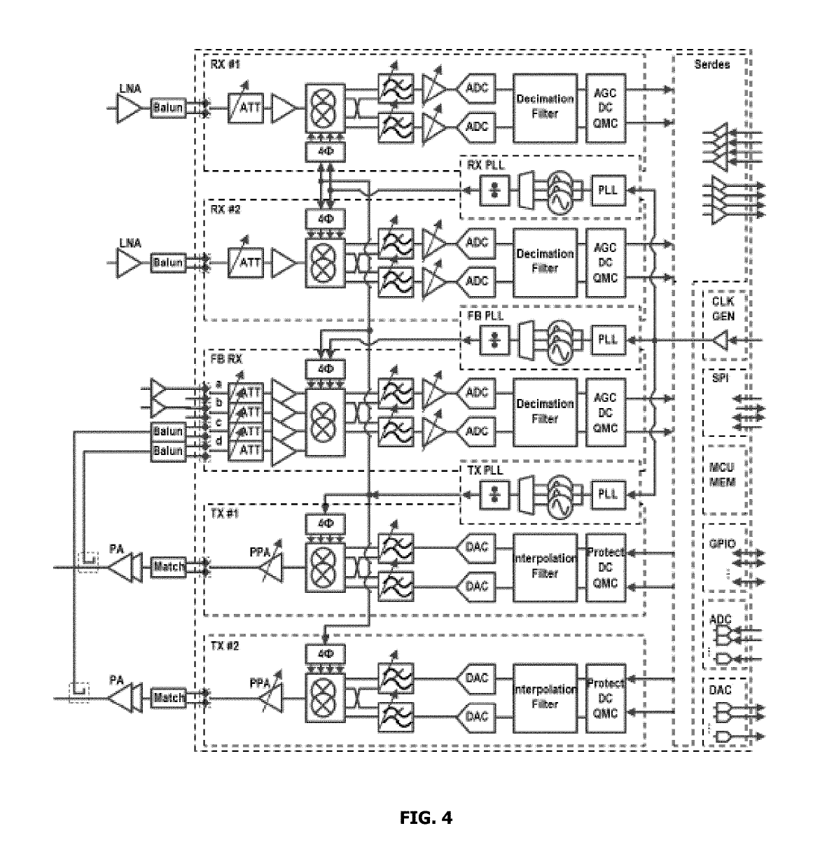

FIG. 1 illustrates a conventional latch, configured with two switched differential inverters, with an inner series switch that is controlled by an incoming clock signal (φ and φ_{bar} or clock and /clock), with cross-coupling PMOS/NMOS.

Each inverter is composed of four devices (two PMOS and two NMOS), in a series/stacked configuration. The inner PMOS/NMOS transistors (drain-connected) form a switch (cross-coupled) used to clock (φ/φ_{ba}) the inverters, while the outer PMOS/NMOS transistors provide the differential latch output (D/Dbar).

FIG. 2 illustrates an example embodiment of a latch design according to this Disclosure.

Essentially, the clock switch (φ/φ_{bar}) is moved to the outer PMOS and NMOS transistors, and the Data (D/D_{bar}) path is moved to the inner transistors. As a design option, since, the clocking transistors of the same polarity (high-side bar and low-side no_bar) for both inverters are respectively at the high-side and low-side rails, they can be combined into single φ_{bar} (high-side) and φ (low side) transistors.

By moving the clocking switches to the outer most transistors of the switched inverter, voltage glitches during the hold phase of the latch can be reduced. By merging the clock devices into a single device, capacitive loading on the clock path is reduced.

Advantages of the latch design according to this Disclosure include: (a) a faster latch, which enables faster and better performing dividers for lower power, and (b) lower parasitics which allows for lower noise and higher divider speed for lower power consumption.

The Disclosure provided by this Description and the Figures sets forth example embodiments and applications illustrating aspects and features of the invention, and does not limit the scope of the invention, which is defined by the claims. Known circuits, connections, functions and operations are not described in detail to avoid obscuring the principles and features of the invention. These example embodiments and applications, including design examples, can be used by ordinarily skilled artisans as a basis for modifications, substitutions and alternatives to construct other embodiments, including adaptations for other applications.

1. A latch circuit, comprising
a first inverter including a D_latching PMOS/NMOS transistor pair, drain-connected at a D node;
a first /clock PMOS transistor coupled between a high rail and the source terminal of the D_latching PMOS transistor;
a first clock NMOS transistor coupled between a low rail and the source terminal of the D_latching NMOS transistor; and
a second inverter including a Dbar_latching PMOS/NMOS transistor pair, drain-connected at a Dbar node;
a second /clock PMOS transistor coupled between the high rail and the source terminal of the Dbar_latching PMOS transistor;
a second clock NMOS transistor coupled between the low rail and the source terminal of the Dbar_latching NMOS transistor; and
a cross-coupling switch circuit connected between the D node and the Dbar node.

2. The circuit of claim 1, wherein
the first and second /clock PMOS transistors are combined as a single /clock PMOS transistor connected between the high rail and the source terminals of respectively the D_latching and Dbar_latching PMOS transistors; and
the first and second clock NMOS transistors are combined as a single clock NMOS transistor connected between the low rail and the source terminals of respectively the D_latching and Dbar_latching NMOS transistors.

3. The circuit of claim 1, further comprising frequency divider incorporating at least one latch circuit.

4. The circuit of claim 2, wherein the frequency divider is a quadrature frequency divider with I and Q paths, and incorporating at least one latch circuit in each of the I and Q paths.
